(19) United States
(12) Patent Application Publication
(10) Pub. No.: US 2017/0330590 A1
(43) Pub. Date: Nov. 16, 2017

(54) SUSPENSION BOARD WITH CIRCUIT AND PRODUCING METHOD THEREOF

(71) Applicant: NITTO DENKO CORPORATION, Osaka (JP)

(72) Inventors: Tomoaki OKUNO, Osaka (JP); Takatoshi SAKAKURA, Osaka (JP); Takahiro TAKANO, Osaka (JP)

(73) Assignee: NITTO DENKO CORPORATION, Osaka (JP)

(21) Appl. No.: 15/584,390

(22) Filed: May 2, 2017

(30) Foreign Application Priority Data
May 12, 2016 (JP) 2016-095973

(51) Int. Cl. G11B 5/48; H05K 1/11; H05K 1/18; H05K 3/30

(52) U.S. Cl. CPC G11B 5/4826; H05K 1/181; H05K 3/303; G11B 5/484; H05K 1/11; H05K 2201/10083

(57) ABSTRACT

A suspension board with circuit includes a first terminal and a second terminal disposed at spaced intervals to each other, a piezoelectric element disposed between the first terminal and the second terminal so as to be electrically connected to the first terminal and the second terminal, a facing portion facing the piezoelectric element at the second terminal-side relative to the center between the first terminal and the second terminal, and a compensation portion compensating a degree of inclination of the piezoelectric element produced at the time of contact of the facing portion with the piezoelectric element at the first terminal-side relative to the center between the first terminal and the second terminal.

### CROSS-REFERENCE TO RELATED APPLICATION

The present application claims priority from Japanese Patent Application No. 2016-095973 filed on May 12, 2016, the contents of which are hereby incorporated by reference into this application.

### BACKGROUND OF THE INVENTION

### Field of the Invention

The present invention relates to a suspension board with circuit, and a producing method thereof, to be specific, to a suspension board with circuit preferably provided in a hard disk drive, and a producing method thereof.

### Description of Related Art

It has been known that the position and the angle of a magnetic head are accurately adjusted by mounting a piezoelectric element on a suspension board with circuit.

For example, a suspension board with circuit including a front-side piezoelectric terminal and a rear-side piezoelectric terminal; a piezoelectric element disposed therebetween; and a thin region facing the piezoelectric element in a thickness direction, while passing between the front-side piezoelectric terminal and the rear-side piezoelectric terminal has been proposed (ref: for example, Japanese Unexamined Patent Publication No. 2012-099204 (FIG. 3)).

The thin region described in Japanese Unexamined Patent Publication No. 2012-099204 (FIG. 3) is positioned at the rear side (rear-side piezoelectric terminal-side) relative to the center between the front-side piezoelectric terminal and the rear-side piezoelectric terminal.

In Japanese Unexamined Patent Publication No. 2012-099204 (FIG. 3), the suspension board with circuit is obtained as follows: first, the front-side piezoelectric terminal, the rear-side piezoelectric terminal, and the thin region are formed; thereafter, a solder ball is provided in each of the front-side piezoelectric terminal and the rear-side piezoelectric terminal; and then, by melting the solder ball, the front-side piezoelectric terminal and the rear-side piezoelectric terminal are electrically connected to the piezoelectric element.

In Japanese Unexamined Patent Publication No. 2012-099204 (FIG. 3), the piezoelectric element is disposed at minute spaced intervals to the thin region.

### SUMMARY OF THE INVENTION

However, according to the layer structure of the suspension board with circuit, the thin region may be in contact with the piezoelectric element. In such a case, when the solder ball is melted, the piezoelectric element is in contact with the above-described thin region, so that the piezoelectric element inclines. To be specific, the piezoelectric element inclines so that, in the thickness direction, the rear end portion of the piezoelectric element is remote from the rear-side piezoelectric terminal, while the front end portion of the piezoelectric element is brought close to the front-side piezoelectric terminal. Then, there is a disadvantage in that compared to a case where the piezoelectric element does not incline, the rear end portion of the piezoelectric element projects in an up-down direction to be brought into contact with a component such as load beam provided in the suspension board with circuit, so that a head gimbal assembly including the suspension board with circuit and the load beam cannot function.

An object of the present invention is to provide a suspension board with circuit having excellent reliability, and a producing method thereof.

The present invention [1] includes a suspension board with circuit including a first terminal and a second terminal disposed at spaced intervals to each other, a piezoelectric element disposed between the first terminal and the second terminal so as to be electrically connected to the first terminal and the second terminal, a facing portion facing the piezoelectric element at the second terminal-side relative to the center between the first terminal and the second terminal, and a compensation portion compensating a degree of inclination of the piezoelectric element produced at the time of contact of the facing portion with the piezoelectric element at the first terminal-side relative to the center between the first terminal and the second terminal.

According to the suspension board with circuit, the degree of inclination of the piezoelectric element produced at the time of contact of the facing portion with the piezoelectric element can be compensated by the compensation portion. Thus, compared to a case where the degree of inclination of the piezoelectric element is not compensated, projection of the end portion of the piezoelectric element caused by the inclination in the thickness direction can be suppressed. As a result, the suspension board with circuit has excellent reliability.

The present invention [2] includes the suspension board with circuit described in the above-described [1], wherein the first terminal has a first facing face facing the piezoelectric element, the second terminal has a second facing face facing the piezoelectric element, the first facing face and the second facing face are disposed at the same position in a facing direction in which the first terminal and the second terminal face the piezoelectric element, the facing portion has a third facing face facing the piezoelectric element, the compensation portion has a fourth facing face facing the piezoelectric element, and the third facing face and the fourth facing face are disposed at the piezoelectric element-side relative to a phantom face along the first facing face and the second facing face in the facing direction.

The third facing face of the facing portion is disposed at the piezoelectric element-side relative to the phantom face along the first facing face and the second facing face in the facing direction, so that compared to a case where the degree of inclination of the piezoelectric element is not compensated, the end portion of the piezoelectric element projects toward the piezoelectric element-side.

However, in the suspension board with circuit, the fourth facing face of the compensation portion is disposed at the piezoelectric element-side relative to the phantom face in the facing direction. Thus, the degree of inclination of the piezoelectric element can be surely compensated.

The present invention [3] includes the suspension board with circuit described in the above-described [1] or [2] further including a conductive layer having the first terminal and the second terminal, and an insulating layer supporting the conductive layer, wherein the compensation portion consists of the insulating layer and/or the conductive layer.

When the compensation portion is formed of another member, the structure becomes complicated.

However, in the suspension board with circuit, the compensation portion consists of the insulating layer and/or the conductive layer, so that the structure can be simplified.

The present invention [4] includes a suspension board with circuit including a first terminal and a second terminal disposed at spaced intervals to each other, a facing portion capable of facing a piezoelectric element disposed between the first terminal and the second terminal so as to be electrically connected to the first terminal and the second terminal at the second terminal-side relative to the center between the first terminal and the second terminal, and a compensation portion capable of facing the piezoelectric element at the first terminal-side relative to the center between the first terminal and the second terminal, wherein the compensation portion compensates a degree of inclination of the piezoelectric element produced at the time of contact of the facing portion with the piezoelectric element.

According to the suspension board with circuit, the degree of inclination of the piezoelectric element produced at the time of contact of the facing portion with the piezoelectric element can be compensated by the compensation portion. Thus, compared to a case where the degree of inclination of the piezoelectric element is not compensated, projection of the end portion of the piezoelectric element caused by the inclination in the thickness direction can be suppressed. As a result, the suspension board with circuit has excellent reliability.

The present invention [5] includes a method for producing a suspension board with circuit including a step (1) of disposing a first terminal and a second terminal at spaced intervals to each other; a step (2) of disposing a facing portion, between the first terminal and the second terminal, at the second terminal-side relative to the center between the first terminal and the second terminal; a step (3) of disposing a compensation portion, between the first terminal and the second terminal, at the first terminal-side relative to the center between the first terminal and the second terminal; a step (4) of providing a bonding material capable of being melted by heating in the first terminal and the second terminal; a step (5) of disposing a piezoelectric element to face the bonding material so as to be disposed between the first terminal and the second terminal, and to face the facing portion and the compensation portion; and a step (6) of electrically connecting the piezoelectric element to the first terminal and the second terminal by heating the bonding material, wherein in the step (5) and/or the step (6), the compensation portion compensates a degree of inclination of the piezoelectric element produced at the time of contact of the facing portion with the piezoelectric element.

According to the method, in the step (5) and/or the step (6), the compensation portion compensates the degree of inclination of the piezoelectric element produced at the time of contact of the facing portion with the piezoelectric element. Thus, the degree of inclination of the piezoelectric element produced by contact of the facing portion with the piezoelectric element can be compensated. As a result, compared to a case where the degree of inclination of the piezoelectric element is not compensated, projection of the end portion of the piezoelectric element caused by the inclination in the thickness direction can be suppressed. Therefore, the suspension board with circuit having excellent reliability can be obtained.

The suspension board with circuit obtained by the method for producing a suspension board with circuit of the present invention has excellent reliability.

### BRIEF DESCRIPTION OF THE DRAWINGS

FIG. 1 shows a plan view of one embodiment of a suspension board with circuit of the present invention.

FIG. 2 shows a plan view of the front end portion of the suspension board with circuit shown in FIG. 1.

FIG. 3 shows an enlarged plan view of a front-side piezoelectric terminal, a rear-side piezoelectric terminal, and a facing portion of the suspension board with circuit shown in FIG. 2.

FIG. 4 shows a cross sectional view along an A-A line of the suspension board with circuit shown in FIG. 2.

FIG. 5 shows a perspective view showing the front-side piezoelectric terminal and the rear-side piezoelectric terminal shown in FIG. 3 when viewed from below.

FIGS. 6A to 6G show process drawings for illustrating a method for producing the suspension board with circuit shown in FIG. 4:

FIG. 6A illustrating a step of preparing a metal supporting board,

FIG. 6B illustrating a step of providing a base insulating layer,

FIG. 6C illustrating a step of providing a conductive layer,

FIG. 6D illustrating a step of providing a cover insulating layer,

FIG. 6E illustrating a step of forming a board opening portion,

FIG. 6F illustrating a step of removing the lower end portion of the base insulating layer in a front-side terminal forming portion and a rear-side terminal forming portion, and

FIG. 6G illustrating a step of providing a bonding material and a piezoelectric element.

FIG. 7 shows a suspension board with circuit of prior art for illustrating an embodiment in which inclination of the piezoelectric element is produced by contact of the facing portion with the piezoelectric element.

FIGS. 8A and 8B show process drawings of a modified example of the producing method shown in FIG. 6:

FIG. 8A illustrating a step of providing a piezoelectric element and

FIG. 8B illustrating a step of reflowing the bonding material.

FIG. 9 shows a modified example of the suspension board with circuit shown in FIG. 4 for illustrating an embodiment in which a compensation portion consists of a cover insulating layer.

FIG. 10 shows a modified example of the suspension board with circuit shown in FIG. 4 for illustrating an embodiment in which a compensation portion consists of a conductive layer.

### DETAILED DESCRIPTION OF THE INVENTION

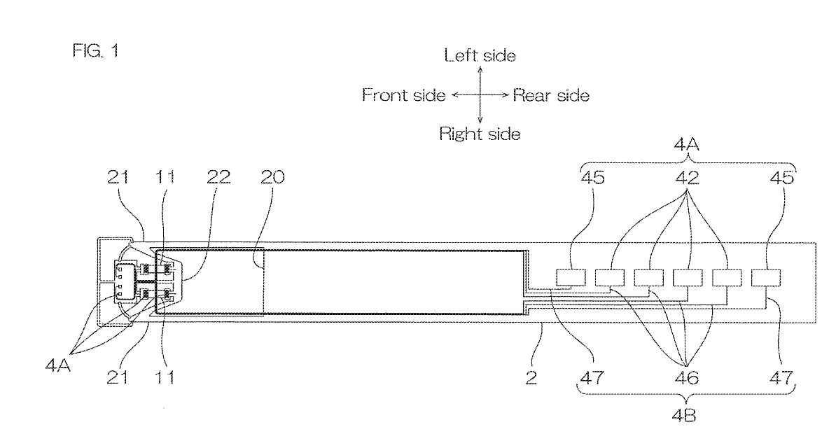

In FIG. 1, right-left direction in the plane of the paper is longitudinal direction (first direction) of a suspension board with circuit, left side in the plane of the paper is front side (one side in the longitudinal direction, one side in the first direction), and right side in the plane of the paper is rear side (the other side in the longitudinal direction, the other side in the first direction).

In FIG. 1, up-down direction in the plane of the paper is width direction (second direction perpendicular to the first direction) of the suspension board with circuit, upper side in the plane of the paper is left side (one side in the second direction), and lower side in the plane of the paper is right side (the other side in the second direction).

In FIG. 1, paper thickness direction in the plane of the paper is thickness direction (third direction perpendicular to the first direction and the second direction, one example of facing direction) of the suspension board with circuit, near side in the plane of the paper is upper side (one side in the third direction), and further side in the plane of the paper is lower side (the other side in the third direction).

The directions are, to be specific, in accordance with the direction arrows described in the figures.

In the following, one embodiment of the suspension board with circuit of the present invention is described with reference to FIGS. 1 to 5.

### 1. Basic Structure of Suspension Board with Circuit

As shown in FIG. 1, a suspension board with circuit 1 has a generally flat plate shape extending in a front-rear direction.

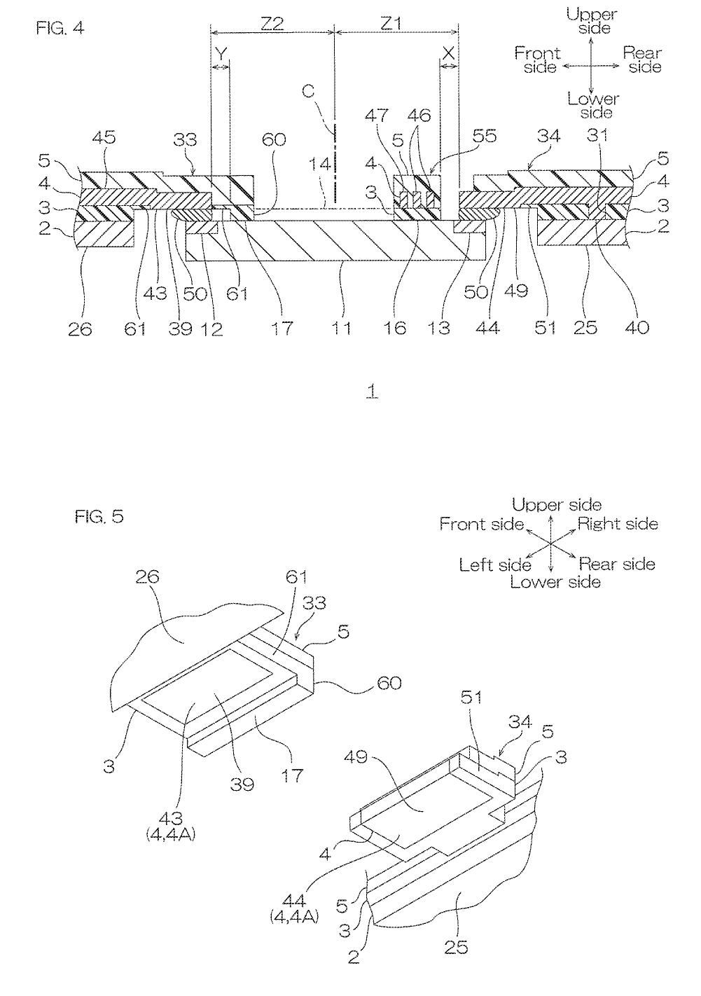

As shown in FIG. 4, the suspension board with circuit 1 includes a metal supporting board 2, a base insulating layer 3 provided thereon, a conductive layer 4 provided on the base insulating layer 3, and a cover insulating layer 5 provided above the base insulating layer 3 so as to cover the conductive layer 4. The suspension board with circuit 1 includes piezoelectric elements 11 as one example of the piezoelectric element.

1-1. Metal Supporting Board

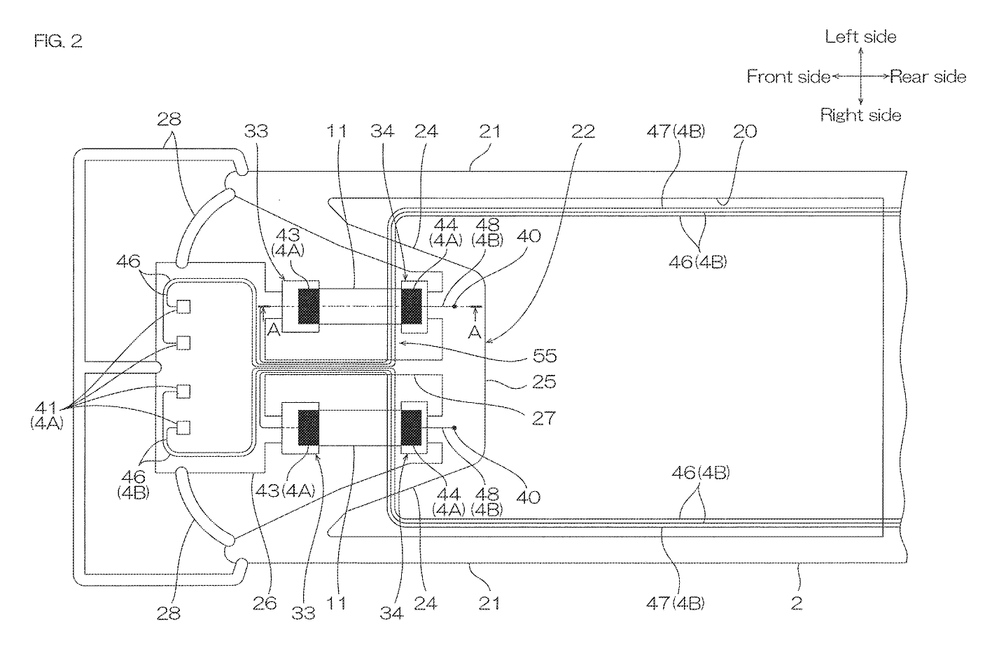

As shown in FIG. 1, the metal supporting board 2 has a generally rectangular flat belt shape when viewed from the top extending in the longitudinal direction. As shown in FIGS. 1 and 2, the metal supporting board 2 has, at the front end portion thereof, a board opening portion 20 in a generally rectangular shape when viewed from the top passing through the metal supporting board 2 in the thickness direction.

The metal supporting board 2 includes, at the front end portion thereof, outrigger portions 21 that are divided outside in the width direction (direction perpendicular to the front-rear direction) of the board opening portion 20, a tongue portion 22 that is connected to the outrigger portions 21, and a first connecting portion 24 that connects the outrigger portions 21 to the tongue portion 22.

The outrigger portions 21 extend in a linear shape from the central portion forwardly in the metal supporting board 2.

The tongue portion 22 is provided inside in the width direction of the outrigger portions 21. The tongue portion 22 is connected to the outrigger portions 21 through the first connecting portion 24. The tongue portion 22 has a generally H-shape when viewed from the top. To be specific, the tongue portion 22 integrally includes a base portion 25 having a generally rectangular shape when viewed from the top extending long in the width direction, a stage 26 disposed at spaced intervals to the front side of the base portion 25 and having a generally rectangular shape when viewed from the top extending long in the width direction, and a second connecting portion 27 connecting the center in the width direction of the base portion 25 to that in the width direction of the stage 26 and having a generally rectangular shape when viewed from the top extending long in the front-rear direction.

The stage 26 is connected to the outrigger portions 21 through a third connecting portion 28. The third connecting portion 28 has a narrow strip shape extending in the front-rear direction.

The first connecting portion 24 has a shape extending from the front end portion of the outrigger portions 21 toward obliquely and inwardly rear side in the width direction.

The metal supporting board 2 is, for example, made of a metal material such as stainless steel. The metal supporting board 2 has a thickness of, for example, 10 μm or more, preferably 15 μm or more, and for example, 50 μm or less, preferably 30 μm or less.

1-2. Base Insulating Layer

As shown in FIG. 4, on the metal supporting board 2, the base insulating layer 3 has a pattern shape corresponding to the conductive layer 4. At the front end portion of the suspension board with circuit 1, the base insulating layer 3 has a base opening portion 31 that is filled with a ground portion 40 (described later), a second thin portion 61 and a compensation portion 60 of a front-side terminal forming portion 33 (described later), and a first thin portion 51 of a rear-side terminal forming portion 34 (described later).

The base opening portion 31 is a through hole that passes through the base insulating layer 3 in the thickness direction.

The details of the second thin portion 61, the compensation portion 60, and the first thin portion 51 are described later.

The base insulating layer 3 is made of an insulating material such as polyimide resin. The base insulating layer 3 has a thickness of, for example, 1 μm or more, preferably 3 μm or more, and for example, 35 μm or less, preferably 30 μm or less.

1-3. Conductive Layer

As shown in FIGS. 1 and 2, the conductive layer 4 is a conductive pattern including terminals 4A, the ground portions 40, and wires 4B. The terminals 4A include head-side terminals 41, outer-side terminals 42, front-side piezoelectric terminals 43 as one example of the first terminal, rear-side piezoelectric terminals 44 as one example of the second terminal, and power source-side terminals 45. The wires 4B include signal wires 46, power wires 47, and ground wires 48.

The head-side terminals 41 are provided at the front end portion of the stage 26. A plurality (four pieces) of head-side terminals 41 are disposed at spaced intervals to each other in the width direction.

The outer-side terminals 42 are provided at the rear end portion of the suspension board with circuit 1. A plurality (four pieces) of outer-side terminals 42 are disposed at spaced intervals to each other in the front-rear direction.

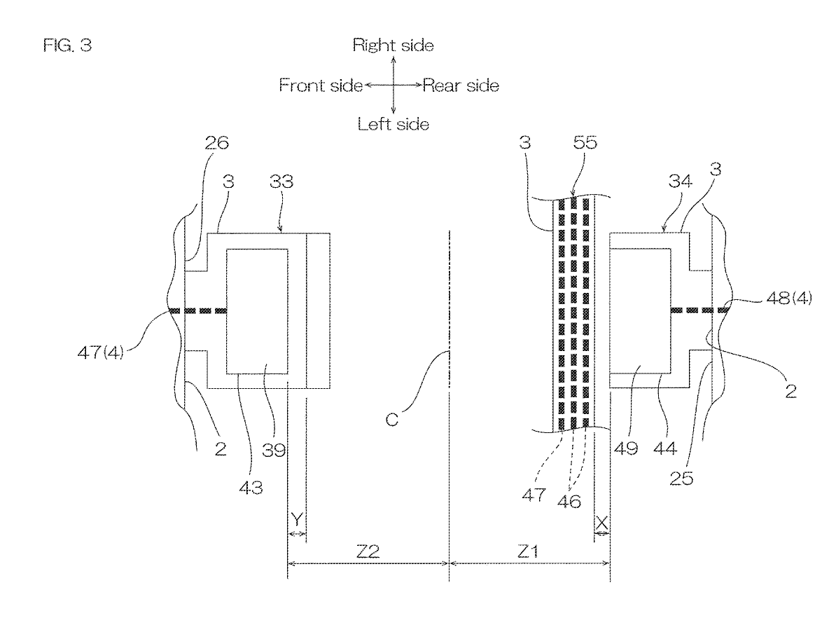

The front-side piezoelectric terminals 43 are positioned immediately at the rear side of the stage 26. The front-side piezoelectric terminals 43 project from the rear end edge of the outer-side portion in the width direction of the stage 26 rearwardly. The front-side piezoelectric terminals 43 have a land shape. A plurality (two pieces) of front-side piezoelectric terminals 43 are disposed at spaced intervals to each other in the width direction at both outer sides in the width direction of the second connecting portion 27. As shown in FIGS. 3 to 5, a third lower face 39 as one example of the first facing face of each of the two front-side piezoelectric terminals 43 is exposed from the base insulating layer 3 downwardly.

As shown in FIGS. 2 and 3, the rear-side piezoelectric terminals 44 are positioned immediately at the front side of the base portion 25. The rear-side piezoelectric terminals 44 have a land shape corresponding to the front-side piezoelectric terminals 43. The rear-side piezoelectric terminals 44 are formed at spaced intervals to the rear side of the plurality (two pieces) of front-side piezoelectric terminals 43. Each of the plurality (two pieces) of rear-side piezoelectric terminals 44 projects from the front end edge of the outer-side portion in the width direction of the base portion 25 forwardly. Each of the plurality (two pieces) of rear-side piezoelectric terminals 44 has a land shape. The plurality (two pieces) of rear-side piezoelectric terminals 44 are disposed at spaced intervals to each other in the width direction. As shown in FIGS. 4 and 5, a fourth lower face 49 as one example of the second facing face of each of the two rear-side piezoelectric terminals 44 is exposed from the base insulating layer 3 downwardly.

The third lower face 39 of the front-side piezoelectric terminal 43 and the fourth lower face 49 of the rear-side piezoelectric terminal 44 are overlapped when projected in the front-rear direction. Thus, the third lower face 39 and the fourth lower face 49 form a first phantom face 14 as one example of the phantom face along the front-rear direction.

As shown in FIG. 1, a plurality (two pieces) of power source-side terminals 45 are disposed at spaced intervals to each other at both sides in the front-rear direction of the outer-side terminals 42 at the rear end portion of the suspension board with circuit 1.

As shown in FIG. 2, the ground portions 40 are disposed at both end portions in the right-left direction of the tongue portion 22. As shown in FIG. 4, the ground portion 40 fills the base opening portion 31. Thus, the ground portion 40 is in direct contact with the upper face of the metal supporting board 2 exposed from the base opening portion 31.

As shown in FIGS. 1 and 2, the signal wires 46 have a pattern shape connecting the head-side terminals 41 to the outer-side terminals 42, and are disposed in parallel at spaced intervals to each other. At the rear end portion of the suspension board with circuit 1, the signal wires 46 extend from the outer-side terminals 42 forwardly; bend in a branched state into two bundles toward both outer sides in the width direction at the center in the front-rear direction of a main body portion 3; and then, extend toward the front end portion of the board opening portion 20. Thereafter, the signal wires 46 bend inwardly; go through between the first connecting portion 24, and the front-side piezoelectric terminals 43 and the rear-side piezoelectric terminals 44 to reach in a bundled state at the rear end portion of the second connecting portion 27; and subsequently, bend forwardly to then extend forwardly along the second connecting portion 27 to reach the rear end portion of the stage 26. Furthermore, the signal wires 46 bend in a branched state into two bundles toward both outer sides in the width direction; then, extend along the circumference end edge of the stage 26; and thereafter, are folded back at the front end portion of the stage 26 to reach the head-side terminals 41.

As shown in FIGS. 3 and 4, between the front-side piezoelectric terminals 43 and the rear-side piezoelectric terminals 44, the signal wires 46 go through a space at the rear side relative to a central portion C in the front-rear direction (that is, the rear-side piezoelectric terminal 44-side) between the front-side piezoelectric terminals 43 and the rear-side piezoelectric terminals 44.

As shown in FIGS. 1 and 2, the power wires 47 have a pattern shape connecting the power source-side terminals 45 to the front-side piezoelectric terminals 43, and are disposed in parallel at spaced intervals to each other. The power wires 47 are in parallel with the signal wires 46 outside of the signal wires 46 at spaced intervals thereto. The power wires 47 bend from both end portions in the width direction of the rear end portion of the stage 26 rearwardly and go toward the front-side piezoelectric terminals 43. As shown in FIG. 3, the power wires 47, along with the signal wires 46, go through the space at the rear side relative to the central portion C in the front-rear direction between the front-side piezoelectric terminals 43 and the rear-side piezoelectric terminals 44.

As shown in FIGS. 2 and 4, the ground wires 48 have a generally linear shape when viewed from the top connecting the rear-side piezoelectric terminals 44 to the ground portions 40. To be specific, the ground wires 48 extend from the upper portions of the ground portions 40 forwardly to reach the rear-side piezoelectric terminals 44.

The conductive layer 4 is, for example, made of a conductive material such as copper. The conductive layer 4 has a thickness of, for example, 3 μm or more, preferably 5 μm or more, and for example, 50 μm or less, preferably 20 μm or less.

1-4. Cover Insulating Layer

As shown in FIG. 4, the cover insulating layer 5 has a pattern shape covering the conductive layer 4 above the base insulating layer 3. To be specific, the cover insulating layer 5 has a pattern shape exposing the head-side terminal 41, the outer-side terminal 42, and the power source-side terminal 45.

As shown in FIGS. 3 and 4, the base insulating layer 3, the signal wire 46, the power wire 47, and the cover insulating layer 5 constitute a facing portion 55 in a portion where the signal wire 46 and the power wire 47 go through between the front-side piezoelectric terminal 43 and the rear-side piezoelectric terminal 44.

The facing portion 55 is a member provided unavoidably in the suspension board with circuit 1 in accordance with the shape and the size of the metal supporting board 2, and the arrangement of the conductive layer 4.

The facing portion 55 includes the base insulating layer 3, the signal wire 46, the power wire 47, and the cover insulating layer 5. Preferably, the facing portion 55 consists of only the base insulating layer 3, the signal wire 46, the power wire 47, and the cover insulating layer 5.

A first lower face 16 as one example of the third facing face of the facing portion 55 consists of the base insulating layer 3. The first lower face 16 is positioned at the lower side (piezoelectric element 11-side to be described later) relative to the first phantom face 14. The first phantom face 14 goes through a midway portion in the thickness direction of the facing portion 55.

The upper face of the facing portion 55 consists of the cover insulating layer 5.

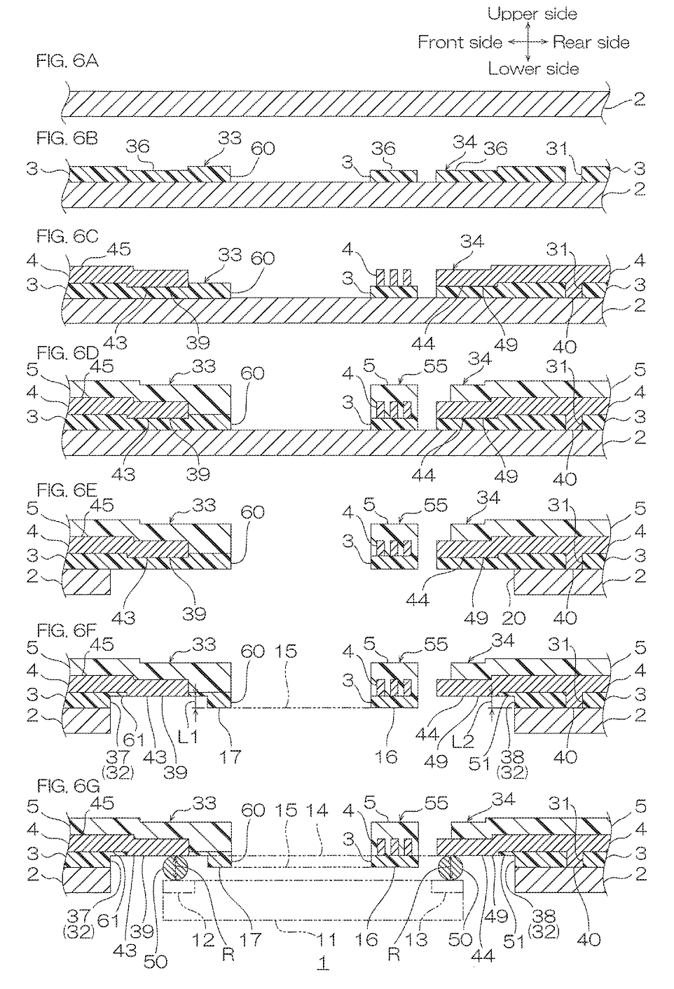

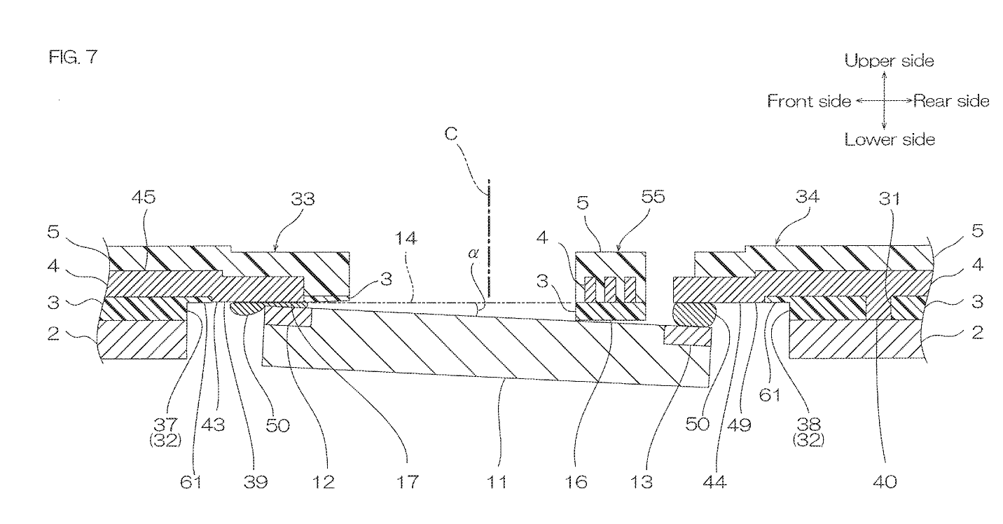

As shown in FIG. 7, the facing portion 55 is a member which is in contact with the rear-side portion of the piezoelectric element 11 to push it downwardly, and produces inclination of the piezoelectric element 11 that allows the piezoelectric element 11 to gradually incline downwardly toward the rear side at the time of reflow of a bonding material 50 to be described later (ref: FIGS. 6G and 4).

A percentage ((X/Z1)×100) of a distance X between the front end face of the rear-side piezoelectric terminal 44 and the rear end face of the facing portion 55 to a distance Z1 between the front end face of the rear-side piezoelectric terminal 44 and the central portion C in the front-rear direction is, for example, above 0%, preferably 5% or more, and for example, below 100%, preferably 80% or less.

The base insulating layer 3 and the cover insulating layer 5 support the front-side piezoelectric terminal 43, and the base insulating layer 3, the front-side piezoelectric terminal 43, and the cover insulating layer 5 constitute the front-side terminal forming portion 33. The details of the front-side terminal forming portion 33 are described later.

Furthermore, the base insulating layer 3 and the cover insulating layer 5 support the rear-side piezoelectric terminal 44, and the base insulating layer 3, the rear-side piezoelectric terminal 44, and the cover insulating layer 5 constitute the rear-side terminal forming portion 34. The details of the rear-side terminal forming portion 34 are described later.

The cover insulating layer 5 is made of the same insulating material as that of the base insulating layer 3. The cover insulating layer 5 has a thickness of, for example, 1 μm or more, preferably 3 μm or more, and for example, 40 μm or less, preferably 10 μm or less.

1-5. Piezoelectric Element

As shown in FIG. 2, the piezoelectric elements 11 are disposed at both outer sides in the width direction of the second connecting portion 27. Each of the two piezoelectric elements 11 is disposed between the front-side piezoelectric terminal 43 and the rear-side piezoelectric terminal 44.

As shown in FIGS. 2 and 4, each of the two piezoelectric elements 11 extends in the front-rear direction. Each of the two piezoelectric elements 11 has a generally rectangular flat plate shape. A front-side electrode 12 and a rear-side electrode 13 are provided at both end portions in the front-rear direction of each of the upper faces of the two piezoelectric elements 11.

The front-side electrode 12 faces the third lower face 39 of the front-side piezoelectric terminal 43 in the thickness direction. The front-side electrode 12 is electrically connected to the front-side piezoelectric terminal 43 through the bonding material 50.

The rear-side electrode 13 faces the fourth lower face 49 of the rear-side piezoelectric terminal 44. The rear-side electrode 13 is electrically connected to the rear-side piezoelectric terminal 44 through the bonding material 50.

The piezoelectric element 11 is, for example, made of lead, zinc, titanium, zirconium, or an alloy thereof, and lead zirconate titanate (complex oxide such as Pb (Zr, Ti)O₃).

The length of the piezoelectric element 11 is set to be a distance between the front-side piezoelectric terminal 43 and the rear-side piezoelectric terminal 44 or more and to be specific, for example, 0.5 mm or more, preferably 0.6 mm or more, and for example, 3 mm or less, preferably 2.5 mm or less. The piezoelectric element 11 has a thickness of, for example, 0.02 mm or more, preferably 0.03 mm or more, and for example, 0.15 mm or less, preferably 0.1 mm or less.

### 2. Rear-Side Terminal Forming Portion and Front-Side Terminal Forming Portion (Including Compensation Portion)

The details of the rear-side terminal forming portion 34 and the front-side terminal forming portion 33 (including the compensation portion 60) are described.

2-1. Rear-Side Terminal Forming Portion

As shown in FIGS. 3 to 5, the rear-side terminal forming portion 34 is a member including the rear-side piezoelectric terminal 44, and larger than the rear-side piezoelectric terminal 44 when viewed from the top. The rear-side terminal forming portion 34 has a generally rectangular shape. As shown in FIG. 2, the rear-side terminal forming portion 34 is disposed at the front side of the base portion 25.

The rear-side terminal forming portion 34 includes the base insulating layer 3, the rear-side piezoelectric terminal 44, and the cover insulating layer 5. Preferably, the rear-side terminal forming portion 34 consists of only the base insulating layer 3, the rear-side piezoelectric terminal 44, and the cover insulating layer 5.

In the rear-side terminal forming portion 34, the base insulating layer 3 projects from the base portion 25 forwardly. The base insulating layer 3 has a generally rectangular shape when viewed from the bottom. The base insulating layer 3 in the rear-side terminal forming portion 34 is the first thin portion 51 that is thinner than the base insulating layer 3 in the base portion 25. As shown in FIG. 5, the lower face of the first thin portion 51 is flush with the fourth lower face 49 of the rear-side piezoelectric terminal 44 in a surface direction (direction along the front-rear direction and the width direction). The front end face of the first thin portion 51 is flush with the front end face of the rear-side piezoelectric terminal 44 in the width direction. Although described in the method for producing the suspension board with circuit 1, the first thin portion 51 is formed by removing the lower end portion of the base insulating layer 3 in the rear-side terminal forming portion 34.

As shown in FIG. 3, in the rear-side terminal forming portion 34, the rear-side piezoelectric terminal 44 has a generally rectangular shape when viewed from the bottom. The rear-side piezoelectric terminal 44 has a land shape. As shown in FIG. 4, the rear end portion of the rear-side piezoelectric terminal 44 is disposed on the first thin portion 51 of the base insulating layer 3. Meanwhile, the front end portion, and the central portion in the front-rear direction of the rear-side piezoelectric terminal 44 are positioned to fall one step from the rear end portion. The fourth lower face 49 of the front end portion, and the central portion in the front-rear direction of the rear-side piezoelectric terminal 44 is exposed from the base insulating layer 3 downwardly. As shown in FIGS. 4 and 5, the fourth lower face 49 of the front end portion, and the central portion in the front-rear direction of the rear-side piezoelectric terminal 44 is flush with the lower face of the first thin portion 51 of the base insulating layer 3 in the front-rear direction and the width direction.

In the rear-side terminal forming portion 34, the cover insulating layer 5 projects from the base portion 25 forwardly. The rear-side terminal forming portion 34 has a generally rectangular shape when viewed from the bottom. The cover insulating layer 5 covers both side faces in the right-left direction of the rear end portion, and the central portion in the front-rear direction of the rear-side piezoelectric terminal 44. Meanwhile, the cover insulating layer 5 exposes the upper face, the front end face, and both side faces in the right-left direction of the front end portion of the rear-side piezoelectric terminal 44 toward the upper side, the front side, and both sides in the right-left direction, respectively.

2-2. Front-Side Terminal Forming Portion

The front-side terminal forming portion 33 is a member including the front-side piezoelectric terminal 43, and larger than the front-side piezoelectric terminal 43 when viewed from the bottom. The front-side terminal forming portion 33 has a generally rectangular plate shape. The front-side terminal forming portion 33 is disposed at the rear side of the stage 26.

The front-side terminal forming portion 33 includes the base insulating layer 3, the front-side piezoelectric terminal 43, and the cover insulating layer 5. Preferably, the front-side terminal forming portion 33 consists of only the base insulating layer 3, the front-side piezoelectric terminal 43, and the cover insulating layer 5.

In the front-side terminal forming portion 33, the base insulating layer 3 projects from the stage 26 rearwardly. The base insulating layer 3 has a generally rectangular shape when viewed from the bottom. The front-side terminal forming portion 33 has the second thin portion 61 that is relatively thin, and the compensation portion 60 that is a thicker thick portion than the second thin portion 61.

The second thin portion 61 in the front-side terminal forming portion 33 is thinner than the base insulating layer 3 in the stage 26. The lower face of the second thin portion 61 is flush with the third lower face 39 of the front-side piezoelectric terminal 43 in the surface direction.

The compensation portion 60 is provided continuously from the rear side of the second thin portion 61. The upper face of the compensation portion 60 is flush with the upper face of the second thin portion 61. Meanwhile, a second lower face 17 as one example of the fourth facing face of the compensation portion 60 is positioned at the lower side relative to the lower face of the second thin portion 61. The compensation portion 60 in the front-side terminal forming portion 33 has the same thickness as that of the base insulating layer 3 in the stage 26. The compensation portion 60 makes the lower end portion of the base insulating layer 3 in the front-side terminal forming portion 33.

In this manner, the base insulating layer 3 in the front-side terminal forming portion 33 extends in the front-rear direction, and has a generally L-shape when viewed from the side in which the rear end portion thereof bends downwardly.

The second lower face 17 of the compensation portion 60 is positioned at the lower side (piezoelectric element 11-side to be described later) relative to the first phantom face 14. Preferably, the second lower face 17 of the compensation portion 60 is overlapped with the first lower face 16 of the facing portion 55 when projected in the front-rear direction. That is, as shown in FIG. 6F, the second lower face 17 of the compensation portion 60 and the first lower face 16 of the facing portion 55 form the same, that is, a second phantom face 15. The second phantom face 15 is in parallel with the first phantom face 14, and is positioned at the lower side (piezoelectric element 11-side) relative to the first phantom face 14.

Although described later, the compensation portion 60 is an inclination degree compensation member that compensates the inclination of the piezoelectric element 11 shown in FIG. 7 produced when the facing portion 55 provided unavoidably in the suspension board with circuit 1 is brought into contact with (pushes down) the rear-side portion of the piezoelectric element 11 at the time of reflow of the bonding material 50 (ref: FIGS. 6G and 4). The compensation portion 60 is an originally unnecessary member for the suspension board with circuit 1 not including the facing portion 55, but a necessary member for the suspension board with circuit 1 including the facing portion 55.

Although described in the method for producing the suspension board with circuit 1, the second thin portion 61 and the compensation portion 60 are formed by removing the lower end portion of the base insulating layer 3 in the front-side terminal forming portion 33.

As shown in FIG. 3, in the front-side terminal forming portion 33, the front-side piezoelectric terminal 43 has a generally rectangular shape when viewed from the bottom. The front-side piezoelectric terminal 43 has a land shape. As shown in FIG. 4, the front end portion of the front-side piezoelectric terminal 43 is disposed on the rear end portion of the base insulating layer 3. Meanwhile, the rear end portion, and the central portion in the front-rear direction of the front-side piezoelectric terminal 43 are positioned to fall one step from the front end portion. The third lower face 39 of the rear end portion, and the central portion in the front-rear direction of the front-side piezoelectric terminal 43 is exposed from the base insulating layer 3 downwardly. As shown in FIGS. 4 and 5, the third lower face 39 is flush with the lower face of the second thin portion 61 of the base insulating layer 3 in the front-rear direction and the width direction.

In the front-side terminal forming portion 33, the front-side piezoelectric terminal 43 is disposed at spaced intervals to the front side of the compensation portion 60. The front-side piezoelectric terminal 43 is surrounded by the thin portion 61 of the base insulating layer 3 when viewed from the bottom.

A percentage ((Y/Z2)×100) of a distance Y between the rear end face of the front-side piezoelectric terminal 43 and the front end face of the compensation portion 60 to a distance Z2 between the rear end face of the front-side piezoelectric terminal 43 and the central portion C in the front-rear direction is, for example, above 0%, preferably 5% or more, and for example, below 100%, preferably below 80%. The above-described Z2 is the same as Z1.

A percentage ((Y/X)×100) of the distance Y between the front-side piezoelectric terminal 43 and the compensation portion 60 to the distance X between the rear-side piezoelectric terminal 44 and the facing portion 55 is, for example, 10% or more, preferably 50% or more, and for example, 300% or less, preferably 200% or less.

In the front-side terminal forming portion 33, the cover insulating layer 5 projects from the stage 26 rearwardly. The front-side terminal forming portion 33 has a generally rectangular shape when viewed from the bottom. The cover insulating layer 5 covers the upper face, the rear end face, and both side faces in the right-left direction of the front-side piezoelectric terminal 43.

2-3. Contact of Facing Portion and Compensation Portion with Piezoelectric Element

The first lower face 16 of the facing portion 55 is in direct contact with the upper face of the rear-side portion (portion at the rear side relative to the central portion C in the front-rear direction and immediately at the front side of the rear-side electrode 13) of the piezoelectric element 11.

Meanwhile, the second lower face 17 of the compensation portion 60 is in direct contact with the upper face of the front-side portion (portion at the front side relative to the central portion C in the front-rear direction and immediately at the rear side of the front-side electrode 12) of the piezoelectric element 11. As shown in FIGS. 3 and 4, the compensation portion 60 is in direct contact with the upper face of the piezoelectric element 11 at the front side (front-side piezoelectric terminal 43-side) relative to the central portion C in the front-rear direction between the front-side piezoelectric terminal 43 and the rear-side piezoelectric terminal 44. In this manner, the compensation portion 60 serves as a pedestal supporting the front-side portion of the piezoelectric element 11.

In this manner, as shown in FIG. 6F, the upper face of the piezoelectric element 11 is positioned above the second phantom face 15 (ref: FIG. 6F). That is, the upper face of the piezoelectric element 11 is overlapped with the second phantom face 15 when projected in the right-left direction.

### 3. Method for Producing Suspension Board with Circuit

A method for producing the suspension board with circuit 1 is described with reference to FIGS. 6A to 6G and FIG. 4.

As shown in FIG. 6A, in this method, first, the metal supporting board 2 is prepared.

As shown in FIG. 6B, in this method, next, the base insulating layer 3 is provided on the metal supporting board 2. At this time, the base insulating layer 3 is formed so that a portion corresponding to the front-side piezoelectric terminal 43, the rear-side piezoelectric terminal 44, and the facing portion 55 provided in the next step is a thin portion 36 that is thinner than the periphery thereof. Also, the base opening portion 31 is formed in the base insulating layer 3.

As shown in FIG. 6C, in this method, next, the conductive layer 4 is provided.

The conductive layer 4 is formed on the base insulating layer 3 in a pattern including the terminal 4A (including the front-side piezoelectric terminal 43 and the rear-side piezoelectric terminal 44) and the wire 4B (one example of the steps (1) to (3)).

The ground portion 40 is provided on the metal supporting board 2 exposed from the base opening portion 31. The ground portion 40 fills the base opening portion 31.

As shown in FIG. 6D, in this method, next, the cover insulating layer 5 is provided above the base insulating layer 3 so as to cover the conductive layer 4. In this manner, the front-side terminal forming portion 33, the rear-side terminal forming portion 34, and the facing portion 55 are made.

As shown in FIG. 6E, in this method, next, the board opening portion 20 is formed in the metal supporting board 2.

To be specific, the metal supporting board 2 corresponding to the facing portion 55, the front-side terminal forming portion 33, and the rear-side terminal forming portion 34 is removed. In this manner, the base insulting layer 3 of the facing portion 55, the front-side terminal forming portion 33, and the rear-side terminal forming portion 34 is exposed.

As shown in FIG. 6F, in this method, next, the lower end portion of the base insulating layer 3 in the front-side terminal forming portion 33 and the rear-side terminal forming portion 34 is removed.

To be specific, the lower end portion of the front end portion, and the central portion in the front-rear direction of the base insulating layer 3 in the front-side terminal forming portion 33 is removed, so that the third lower face 39 of the front-side piezoelectric terminal 43 is exposed downwardly. In this manner, the compensation portion 60 and the second thin portion 61 are formed. The lower face of the second thin portion 61 in the base insulating layer 3 is flush with the third lower face 39 of the front-side piezoelectric terminal 43.

Also, by removing the lower end portion of the base insulating layer 3 in the rear-side terminal forming portion 34, the fourth lower face 49 of the rear-side piezoelectric terminal 44 is exposed downwardly. In this manner, the first thin portion 51 is formed. The first thin portion 51 is flush with the fourth lower face 49 of the rear-side piezoelectric terminal 44.

Meanwhile, the base insulating layer 3 in the facing portion 55 is not removed. Thus, the first lower face 16 in the facing portion 55 is positioned at the lower side relative to the third lower face 39 and the fourth lower face 49 when projected in the front-rear direction.

The first lower face 16 of the base insulating layer 3 in the facing portion 55 is overlapped with the second lower face 17 of the compensation portion 60 when projected in the front-rear direction.

A removed thickness L1 in the thickness direction of the base insulating layer 3 of the front-side terminal forming portion 33 is a length L1 obtained by subtracting the thickness of the second thin portion 61 from the thickness of the base insulating layer 3 in the base portion 25, and for example, 1 μm or more, preferably 2 μm or more, and for example, 15 μm or less, preferably 10 μm or less.

A removed thickness L2 in the thickness direction of the base insulating layer 3 of the rear-side terminal forming portion 34 is a length L2 obtained by subtracting the thickness of the first thin portion 51 from the thickness of the compensation portion 60. To be specific, the removed thickness L2 is the same as the removed thickness L1 in the thickness direction of the base insulating layer 3 of the front-side terminal forming portion 33.

As shown in FIG. 6G, in this method, next, the bonding material 50 is provided in the front-side piezoelectric terminal 43 and the rear-side piezoelectric terminal 44 (one example of the step (4)).

The bonding material 50 is made of a bonding material capable of being melted by heating. An example of the bonding material includes solder. The bonding material 50 is solid at normal temperature and for example, has a generally circular shape (ball shape). A diameter R of the bonding material 50 is, for example, above the removed thickness L1 of the base insulating layer 3 of the front-side terminal forming portion 33 and the removed thickness L2 of the base insulating layer 3 of the rear-side terminal forming portion 34, and to be specific, relative to L1 (L2), for example, above 100%, preferably 150% or more, and for example, 1500% or less, preferably 1000% or less.

The bonding material 50 is placed on the third lower face 39 of the front-side piezoelectric terminal 43 and the fourth lower face 49 of the rear-side piezoelectric terminal 44. After the suspension board with circuit 1 is, if necessary, inverted upside down, the bonding material 50 is placed on the front-side piezoelectric terminal 43 and the rear-side piezoelectric terminal 44.

Subsequently, as shown in the phantom line of FIG. 6G, the piezoelectric element 11 is disposed between the front-side piezoelectric terminal 43 and the rear-side piezoelectric terminal 44 (one example of the step (5)).

To be specific, the front-side electrode 12 is disposed to face the third lower face 39 in the thickness direction, and sandwiches the bonding material 50 with the third lower face 39 in the thickness direction. The rear-side electrode 13 is disposed to face the fourth lower face 49 in the thickness direction, and sandwiches the bonding material 50 with the fourth lower face 49 in the thickness direction.

In this manner, the upper face of the piezoelectric element 11 is disposed at minute spaced intervals (for example, above 0 μm, preferably 5 μm or more) to the second lower face 17 and the first lower face 16.

As shown in FIG. 4, in this method, thereafter, the suspension board with circuit 1 is heated, and the bonding material 50 is reflowed (one example of the step (6)).

The heating conditions are set to be the time and the temperature which allow the bonding material 50 to flow so that the front-side electrode 12 can be connected to the rear-side electrode 13, and the front-side piezoelectric terminal 43 can be connected to the rear-side piezoelectric terminal 44.

When the suspension board with circuit 1 is heated, the bonding material 50 flows. Then, the upper face of the piezoelectric element 11 is brought close to the first lower face 16 and the second lower face 17 based on the gravity of the suspension board with circuit 1 (or, the gravity of the piezoelectric element 11 in a case where the suspension board with circuit 1 is inverted upside down), and later, brought into contact with the first lower face 16 and the second lower face 17.

At this time, the compensation portion 60 compensates a degree of inclination of the piezoelectric element 11 produced by contact of the facing portion 55 with the piezoelectric element 11.

That is, as shown in FIG. 7, when the suspension board with circuit 1 does not include the compensation portion 60 (ref: FIG. 4), in the piezoelectric element 11, inclination that allows the piezoelectric element 11 to gradually incline downwardly toward the rear side is produced. The upper face of the piezoelectric element 11 and the first phantom face 14 cross at an acute angle α when viewed in cross section. The angle α is, for example, 3 degrees or more, furthermore 5 degrees or more, furthermore, 10 degrees or more, and below 30 degrees.

However, as shown in FIG. 4, the suspension board with circuit 1 includes the compensation portion 60, so that the compensation portion 60 corrects the above-described inclination. To be specific, the degree of inclination formed between the upper face of the piezoelectric element 11 and the first phantom face 14 is reduced. Specifically, the angle α can be set to, for example, below 10 degrees, preferably below 5 degrees, more preferably below 3 degrees. Most preferably, the angle α is set to 0 degree, that is, the inclination is eliminated.

Thereafter, when the suspension board with circuit 1 is cooled, in a state where the upper face of the piezoelectric element 11 is in contact with the first lower face 16 and the second lower face 17, its position is retained (fixed). Along with this, the front-side electrode 12 is electrically connected to the rear-side electrode 13, and the front-side piezoelectric terminal 43 is electrically connected to the rear-side piezoelectric terminal 44.

Thereafter, a magnetic head (not shown), an external circuit board, and a power source device (not shown) are electrically connected to the head-side terminal 41, the outer-side terminal 42, and the power source-side terminal 45, respectively.

In this manner, the suspension board with circuit 1 is produced.

Thereafter, in the suspension board with circuit 1, the metal supporting board 2 is mounted on a load beam (not shown), and a head gimbal assembly (not shown) including the suspension board with circuit 1 and the load beam is made. Thereafter, the head gimbal assembly is to be mounted on a hard disk drive.

### 1. Operations and Effects of One Embodiment

As shown in FIG. 7, when the suspension board with circuit 1 does not include the compensation portion 60, in the piezoelectric element 11, inclination that allows the piezoelectric element 11 to gradually incline downwardly toward the rear side is produced. Then, the rear end portion projects downwardly. Then, there is a disadvantage in that thereafter, the rear end portion of the piezoelectric element 11 is brought into contact with the load beam (not shown), and the head gimbal assembly cannot swing.

However, as shown in FIG. 4, the suspension board with circuit 1 includes the compensation portion 60 facing the piezoelectric element 11 at the front side relative to the central portion C in the front-rear direction so as to compensate the degree of inclination of the piezoelectric element 11 produced at the time of contact of the facing portion 55 with the piezoelectric element 11. Thus, the degree of inclination of the piezoelectric element 11 produced by contact of the facing portion 55 with the piezoelectric element 11 can be compensated. As a result, the downward projection of the rear end portion of the piezoelectric element 11 caused by the above-described inclination can be suppressed. As a result, the suspension board with circuit 1 has excellent reliability.

In the suspension board with circuit 1, the first lower face 16 of the facing portion 55 is, in the thickness direction, disposed at the lower side relative to the first phantom face 14 (ref: FIG. 6G) along the third lower face 39 and the fourth lower face 49, that is, the piezoelectric element 11-side. Thus, when the compensation portion 60 is not included, as shown in FIG. 7, the downward projection of the rear end portion of the piezoelectric element 11 is produced. However, in the suspension board with circuit 1, as shown in FIG. 4, the second lower face 17 of the compensation portion 60 is, in the thickness direction, disposed at the lower side relative to the first phantom face 14, that is, the piezoelectric element 11-side. Thus, the degree of inclination of the piezoelectric element 11 can be surely compensated.

According to the method, in the step (6) shown in FIG. 4, the compensation portion 60 compensates the degree of inclination of the piezoelectric element 11 produced by contact of the facing portion 55 with the piezoelectric element 11. Thus, the degree of inclination of the piezoelectric element 11 produced by contact of the facing portion 55 with the piezoelectric element 11 can be compensated. As a result, the downward projection of the rear end portion of the piezoelectric element 11 caused by the inclination can be suppressed. Thus, the suspension board with circuit 1 having excellent reliability can be obtained.

### 5. Modified Example

In one embodiment, as shown in FIG. 6G, the piezoelectric element 11 is disposed between the front-side terminal forming portion 33 and the rear-side terminal forming portion 34, and the upper face of the piezoelectric element 11 is disposed at spaced intervals to the first lower face 16 of the facing portion 55 and the second lower face 17 of the compensation portion 60 in the thickness direction. As shown in FIG. 4, thereafter, by reflow of the bonding material 50, the first lower face 16 of the facing portion 55 and the second lower face 17 of the compensation portion 60 are brought into contact with the piezoelectric element 11.

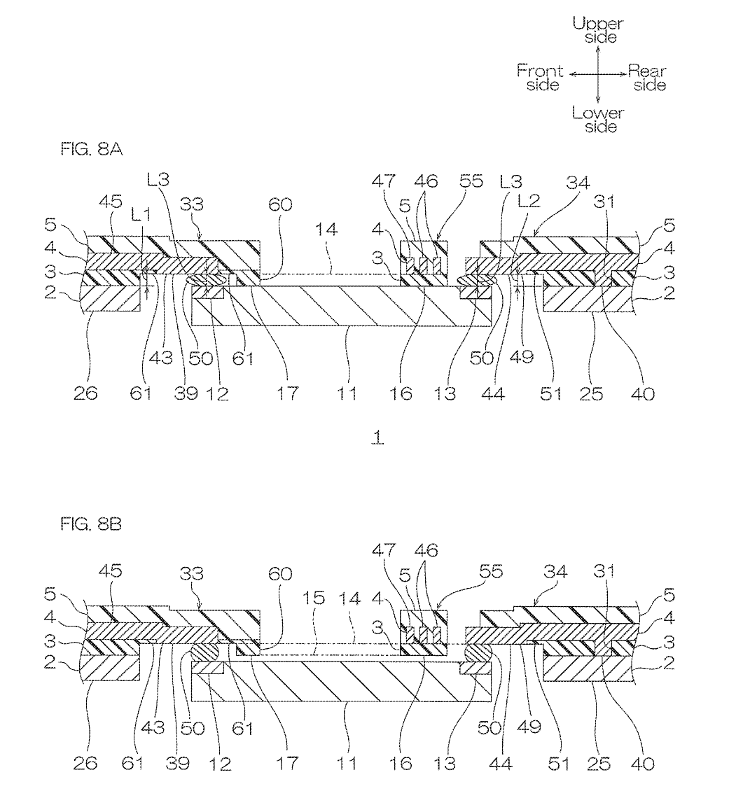

However, for example, as shown in FIG. 8A, the piezoelectric element 11 is disposed between the front-side terminal forming portion 33 and the rear-side terminal forming portion 34, and the first lower face 16 of the facing portion 55 and the second lower face 17 of the compensation portion 60 are brought into contact with the piezoelectric element 11. Thereafter, by reflow of the bonding material 50, the upper face of the piezoelectric element 11 may be disposed at spaced intervals to the first lower face 16 of the facing portion 55 and the second lower face 17 of the compensation portion 60 in the thickness direction, and may not be in contact with the facing portion 55 and the compensation portion 60.

In FIG. 8A, the bonding material 50 sandwiched between the piezoelectric element 11, and the front-side piezoelectric terminal 43 and the rear-side piezoelectric terminal 44 has a flat shape extending in the surface direction. A thickness L3 of the bonding material 50 is, for example, smaller than or equal to the removed thickness L1 and L2 of the base insulating layer 3 described above, preferably, smaller than L1 and L2, and to be specific, below 100%, preferably 80% or less, and for example, 50% or more.

As shown in FIG. 8B, when the bonding material 50 is melted by reflow, the piezoelectric element 11 is pushed downwardly by the bonding material 50 because of the counterforce of the facing portion 55 and the compensation portion 60 relative to the piezoelectric element 11, the surface tension of the bonding material 50, or the like (when the suspension board with circuit 1 is inverted upside down, the piezoelectric element 11 floats up).

In the step in FIG. 8A, the upper face of the piezoelectric element 11 is in contact with the first lower face 16 of the facing portion 55 and the second lower face 17 of the compensation portion 60, and in the subsequent reflow step, as shown in FIG. 4, subsequently such a contact state may be retained. That is, before or after the reflow of the bonding material 50, contact of the piezoelectric element 11 with the facing portion 55 and the compensation portion 60 may be continued.

In the present invention, in the suspension board with circuit 1 of at least any step of in the middle of the production (for example, before reflow) of the suspension board with circuit 1 and after the production (for example, after reflow) of the suspension board with circuit 1, the degree of inclination of the piezoelectric element 11 produced at the time of contact of the facing portion 55 with the piezoelectric element 11 may be compensated by the compensation portion 60. That is, when the piezoelectric element 11 is not inclined, it may not be in contact with the facing portion 55 and the compensation portion 60. However, the suspension board with circuit 1 includes the facing portion 55 and the compensation portion 60, so that the piezoelectric element 11 can be appropriately disposed regardless of the presence or absence of the contact of the facing portion 55 and the compensation 60 with the piezoelectric element 11.

Also, a metal thin film, which is not shown, may be disposed on each of the lower faces of the rear-side piezoelectric terminal 44 and the front-side piezoelectric terminal 43 by, for example, plating. The metal thin film is, for example, made of a metal material such as gold.

In such a case, though not shown in FIG. 5, the lower face of the metal thin film corresponding to the fourth lower face 49 of the rear-side piezoelectric terminal 44 is positioned at the lower side relative to the lower face of the first thin portion 51 with the quantity of the thickness of the first thin portion 51. Also, the lower face of the metal thin film corresponding to the third lower face 39 of the front-side piezoelectric terminal 43 is positioned at the lower side relative to the lower face of the second thin portion 61 with the quantity of the thickness of the metal thin film.

In one embodiment, as shown in FIG. 4, the suspension board with circuit 1 includes the piezoelectric element 11.

However, in the modified example, as shown in FIG. 6F, the suspension board with circuit 1 is made without including the piezoelectric element 11. The suspension board with circuit 1 shown in FIG. 6F is the suspension board with circuit 1 before providing the piezoelectric element 11 therein. The suspension board with circuit 1 is an industrially available device that can be distributed alone even before providing the piezoelectric element 11 therein.

The suspension board with circuit 1 shown in FIG. 6F can also achieve the same operations and effects as those of one embodiment.

In one embodiment shown in FIG. 4, the compensation portion 60 consists of the base insulating layer 3. However, as shown in FIG. 9, the compensation portion 60 may also consist of the cover insulating layer 5.

That is, as shown in FIGS. 4 and 9, the compensation portion 60 can also consist of an insulating layer.

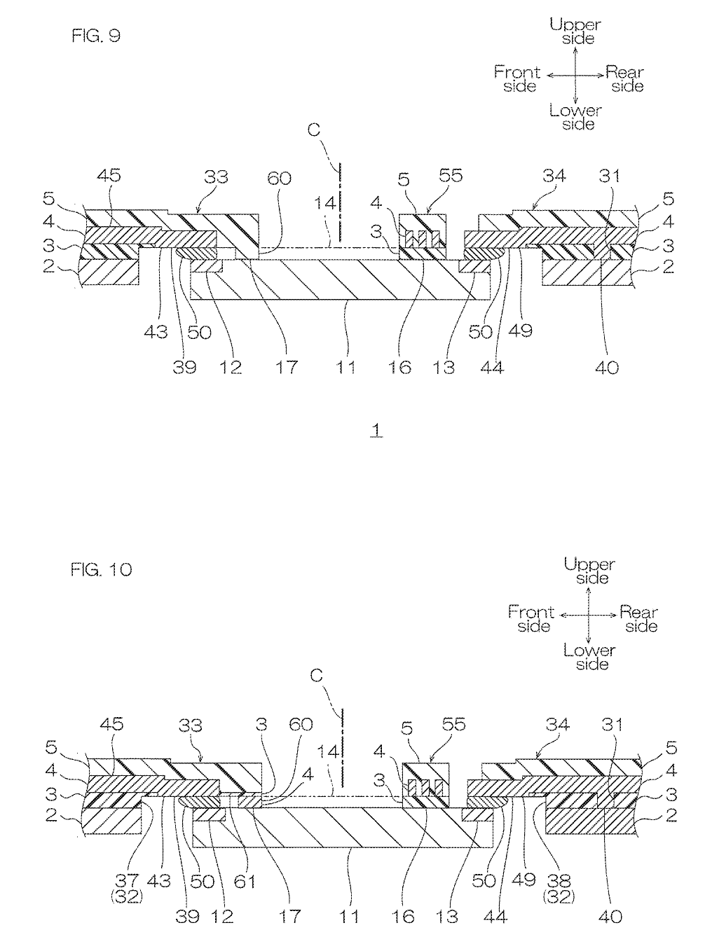

Meanwhile, as shown in FIG. 10, the compensation portion 60 may also consist of the conductive layer 4.

In such a case, the base insulating layer 3 consists of only a thin portion 61 without including a thick portion 60.

The compensation portion 60 is disposed at the rear end portion of the lower face of the thin portion 61.

On the other hand, the compensation portion 60 can be also formed of another member (layer), not any one of the insulating layer and the conductive layer.

Preferably, as shown in FIGS. 4, 9, and 10, the compensation portion 60 consists of at least any one of the insulating layer and the conductive layer.

When the compensation portion 60 is formed of another member, the structure becomes complicated.

However, as shown in FIGS. 4, 9, and 10, when the compensation portion 60 consists of at least any one of the insulating layer and the conductive layer, the structure can be simplified.

In the suspension board with circuit 1 shown in FIG. 4, the facing portion 55 is provided at the rear side relative to the central portion C in the front-rear direction, and the compensation portion 60 is provided at the front side relative to the central portion C in the front-rear direction (to be specific, the front-side terminal forming portion 33).

However, the arrangement of the facing portion 55 and the compensation portion 60 relative to the central portion C in the front-rear direction is not limited to the description above. That is, though not shown, the facing portion 55 can be also provided at the front side relative to the central portion C in the front-rear direction, and the compensation portion 60 can be also provided at the rear side relative to the central portion C in the front-rear direction (to be specific, the rear-side terminal forming portion 34). The modified example can also achieve the same operations and effects as those of one embodiment.

The facing portion 55 and/or the compensation portion 60 have/has the first lower face 16 and/or the second lower face 17, and may be in contact with the piezoelectric element 11 at a point when viewed in cross section (point contact). That is, the facing portion 55 and/or the compensation portion 60 further have/has the lower end portion capable of constituting the second phantom face 15.

Furthermore, the facing portion 55 and/or the compensation portion 60 may not have the first lower face 16 and/or the second lower face 17, and may have the lower end portion capable of being in contact with the piezoelectric element 11 at a point when viewed in cross section (point contact). The lower end portion of the facing portion 55 and/or the compensation portion 60 constitutes the second phantom face 15.

With regard to the number of the compensation portion 60, one compensation portion 60 is provided for one piezoelectric element 11. Alternatively, though not shown, the number thereof may be plural.

While the illustrative embodiments of the present invention are provided in the above description, such is for illustrative purpose only and it is not to be construed as limiting the scope of the present invention. Modification and variation of the present invention that will be obvious to those skilled in the art is to be covered by the following claims.

What is claimed is:

1. A suspension board with circuit comprising:
a first terminal and a second terminal disposed at spaced intervals to each other,
a piezoelectric element disposed between the first terminal and the second terminal so as to be electrically connected to the first terminal and the second terminal,
a facing portion facing the piezoelectric element at the second terminal-side relative to the center between the first terminal and the second terminal, and
a compensation portion compensating a degree of inclination of the piezoelectric element produced at the time of contact of the facing portion with the piezoelectric element at the first terminal-side relative to the center between the first terminal and the second terminal.

2. The suspension board with circuit according to claim 1, wherein
the first terminal has a first facing face facing the piezoelectric element,
the second terminal has a second facing face facing the piezoelectric element,
the first facing face and the second facing face are disposed at the same position in a facing direction in which the first terminal and the second terminal face the piezoelectric element,
the facing portion has a third facing face facing the piezoelectric element,
the compensation portion has a fourth facing face facing the piezoelectric element, and
the third facing face and the fourth facing face are disposed at the piezoelectric element-side relative to a phantom face along the first facing face and the second facing face in the facing direction.

3. The suspension board with circuit according to claim 1 further comprising:
a conductive layer having the first terminal and the second terminal, and
an insulating layer supporting the conductive layer, wherein
the compensation portion consists of the insulating layer and/or the conductive layer.

4. A suspension board with circuit comprising:
a first terminal and a second terminal disposed at spaced intervals to each other,
a facing portion capable of facing a piezoelectric element disposed between the first terminal and the second terminal so as to be electrically connected to the first terminal and the second terminal at the second terminal-side relative to the center between the first terminal and the second terminal, and
a compensation portion capable of facing the piezoelectric element at the first terminal-side relative to the center between the first terminal and the second terminal, wherein
the compensation portion compensates a degree of inclination of the piezoelectric element produced at the time of contact of the facing portion with the piezoelectric element.

5. A method for producing a suspension board with circuit comprising:
a step (1) of disposing a first terminal and a second terminal at spaced intervals to each other;
a step (2) of disposing a facing portion, between the first terminal and the second terminal, at the second terminal-side relative to the center between the first terminal and the second terminal;
a step (3) of disposing a compensation portion, between the first terminal and the second terminal, at the first terminal-side relative to the center between the first terminal and the second terminal;
a step (4) of providing a bonding material capable of being melted by heating in the first terminal and the second terminal;
a step (5) of disposing a piezoelectric element to face the bonding material so as to be disposed between the first terminal and the second terminal, and to face the facing portion and the compensation portion; and
a step (6) of electrically connecting the piezoelectric element to the first terminal and the second terminal by heating the bonding material, wherein
in the step (5) and/or the step (6), the compensation portion compensates a degree of inclination of the piezoelectric element produced at the time of contact of the facing portion with the piezoelectric element.
